(19) United States
(12) Patent Application Publication
(10) Pub. No.: US 2025/0006432 A1
(43) Pub. Date: Jan. 2, 2025

(54) THIN FILM CAPACITOR, SUBSTRATE, AND ELECTRONIC DEVICE

(71) Applicant: TDK CORPORATION, Tokyo (JP)

(72) Inventors: Tadashi IINO, Tokyo (JP); Hiroyasu INOUE, Tokyo (JP); Hitoshi SAITA, Tokyo (JP); Masahiro HIRAOKA, Tokyo (JP)

(73) Assignee: TDK CORPORATION, Tokyo (JP)

(21) Appl. No.: 18/754,832

(22) Filed: Jun. 26, 2024

(30) Foreign Application Priority Data
Jun. 28, 2023 (JP) 2023-105878

(51) Int. Cl. H01G 4/33

(52) U.S. Cl. CPC H01G 4/33

(57) ABSTRACT

A thin film capacitor includes a first electrode layer, a second electrode layer, and a dielectric layer provided between the first electrode layer and the second electrode layer. The thin film capacitor includes an intermediate layer between the dielectric layer and the second electrode layer. The intermediate layer includes at least one stacking unit including a first intermediate layer and a second intermediate layer stacked in contact with the first intermediate layer. The first intermediate layer of the at least one stacking unit closest to the dielectric layer is stacked in contact with the dielectric layer. The first intermediate layer includes a first metal (M1) as a main component. The second intermediate layer includes a second metal (M2), different from the first metal, as a main component.

### BACKGROUND OF THE INVENTION

The present invention relates to a thin film capacitor, a substrate, and an electronic device.

Thin film capacitors can be manufactured by thin film methods, such as sputtering, and are easily embedded into a substrate, so various research and developments are underway. For example, Patent Document 1 describes the development of a thin-film capacitor that does not easily increase ESR even when subjected to heat.

In conventional thin-film capacitors, however, a metal film (e.g., Ni film) having a thickness of about 500 nm is normally formed as a metal layer in contact with the surface of a dielectric layer at a part of an electrode layer formed on the surface of the dielectric layer, in order to protect the dielectric layer, etc. However, conventional thin-film capacitors have problems with peel strength between the dielectric layer and the electrode layer.
Patent Document 1: JP2019169622 (A)

### BRIEF SUMMARY OF THE INVENTION

The present invention has been achieved under such circumstances. It is an object of the invention to provide a thin film capacitor having a high adhesion strength between a dielectric layer and an electrode layer.

To achieve the above object, a thin film capacitor according to a first aspect of the present invention comprises:
a first electrode layer;
a second electrode layer; and
a dielectric layer provided between the first electrode layer and the second electrode layer,
wherein
the thin film capacitor comprises an intermediate layer between the dielectric layer and the second electrode layer,
the intermediate layer comprises at least one stacking unit including a first intermediate layer and a second intermediate layer stacked in contact with the first intermediate layer,
the first intermediate layer of the at least one stacking unit closest to the dielectric layer is stacked in contact with the dielectric layer,
the first intermediate layer comprises a first metal (M1) as a main component, and
the second intermediate layer comprises a second metal (M2), different from the first metal, as a main component.

The present inventors have confirmed that, in the capacitor according to the first aspect, it is possible to set the thickness of the first intermediate layer in contact with the dielectric layer to, for example, less than 100 nm and to set the thickness of the second intermediate layer to, for example, less than 100 nm, and in addition, the adhesion strength between the dielectric layer and the electrode layer can be improved. Moreover, the present inventors have discovered that in this capacitor, reliability such as highly accelerated lifetime test is improved compared to the conventional capacitors.

Preferably, the first intermediate layer has a thickness of 8 to 80 nm, more preferably 8 to 50 nm, and the second intermediate layer has a thickness of 8 to 80 nm, more preferably 8 to 50 nm. The present inventors have discovered for the first time that when the first intermediate layer and the second intermediate layer, which are comparatively thin, are formed so that the first intermediate layer is in contact with the dielectric layer, the adhesion strength between the dielectric layer and the second electrode layer is improved, and the reliability (highly accelerated lifetime test) is improved at the same time.

The reason for this is, for example, as follows. The first metal, which is the main component of the first intermediate layer, reacts with oxygen contained in the dielectric layer during an annealing treatment of the second electrode layer and is strongly bonded with the dielectric layer. During the heat treatment, the first metal, which is the main component of the first intermediate layer, and the second metal, which is the main component of the second intermediate layer, are alloyed, the first metal is prevented from excessively reacting with the dielectric layer, the characteristics of the dielectric layer are prevented from deteriorating, and reliability such as highly accelerated lifetime test is also improved. Moreover, when the first intermediate layer and the second intermediate layer are thin within a predetermined range, the first metal is prevented from excessively reacting with the dielectric layer, and the characteristics of the dielectric are prevented from deteriorating.

Preferably, the first metal (M1) comprises at least one selected from a group consisting of Cu, Cr, Au, Ru, Rh, Ir, Mo, Ti, and W, and the second metal (M2) comprises at least one selected from a group consisting of Ni, Pd, Pt, Au, Ru, Rh, and Ir. Preferably, the first metal is a metal that reacts more with the dielectric layer than the second metal during heat treatment such as annealing of the second electrode layer. Preferably, the second metal is a metal that forms an alloy with the first metal during heat treatment such as annealing of the second electrode layer and prevents the first metal from moving toward the dielectric layer.

Preferably, at least one stacking unit comprises stacking units repeatedly stacked in a range of 2 to 10 in the intermediate layer. When the number of repetition of stacking units is within a predetermined range, reliability is improved, and adhesion is also improved.

A ratio (t2/t1) of a thickness (t2) of the second intermediate layer to a thickness (t1) of the first intermediate layer is not limited, but is preferably 0.2 to 1.0 and is more preferably 0.32 to 0.64. When this ratio is set to an appropriate range, reliability is improved, and adhesion is also improved.

A thin film capacitor according to a second aspect of the present invention comprises:
a first electrode layer;
a second electrode layer; and
a dielectric layer provided between the first electrode layer and the second electrode layer,
wherein
the thin film capacitor comprises an intermediate layer between the dielectric layer and the second electrode layer,
the intermediate layer comprises at least one stacking unit including a first intermediate layer and a second intermediate layer stacked in contact with the first intermediate layer,
the first intermediate layer of the at least one stacking unit closest to the dielectric layer is stacked in contact with the dielectric layer,
the first intermediate layer comprises a second metal (M2) as a main component,
the second intermediate layer comprises a first metal (M1), different from the second metal, as a main component,
the first intermediate layer has a thickness of 8 to 80 nm, and
the second intermediate layer has a thickness of 8 to 80 nm.

In the capacitor according to the second aspect, the thickness of the first intermediate layer in contact with the dielectric layer is as thin as 80 nm or less, and the thickness of the second intermediate layer is also as thin as 80 nm or less. The present inventors have discovered for the first time that since the first intermediate layer and the second intermediate layer, which are comparatively thin, are formed so that the first intermediate layer is in contact with the dielectric layer, the adhesion strength between the dielectric layer and the second electrode layer is improved, and the reliability (highly accelerated lifetime test) is improved at the same time.

The reason for this is, for example, as follows. The first metal, which is the main component of the second intermediate layer, is diffused into the first intermediate layer, which is comparatively thin, and reacts with the dielectric layer during an annealing treatment of the second electrode layer. Then, the first metal reacts with oxygen contained in the dielectric layer and is strongly bonded with the dielectric layer. During the heat treatment, the second metal, which is the main component of the first intermediate layer, and the first metal, which is the main component of the second intermediate layer, are alloyed, the first metal is prevented from excessively reacting with the dielectric layer, the characteristics of the dielectric are prevented from deteriorating, and reliability such as highly accelerated lifetime test is also improved. Moreover, since the first intermediate layer and the second intermediate layer are thin within a predetermined range, the first metal is prevented from excessively reacting with the dielectric layer, and the characteristics of the dielectric are prevented from deteriorating.

Preferably, the first metal is a metal that has a faster diffusion rate than the second metal and reacts with the dielectric layer more than the second metal during heat treatment such as annealing of the second electrode layer. Preferably, the second metal is a metal that forms an alloy with the first metal and prevents the first metal from moving toward the dielectric layer during heat treatment such as annealing of the second electrode layer.

Preferably, the at least one stacking unit comprises stacking units repeatedly stacked in a range of 4 to 10 in the intermediate layer. When the number of repetition of stacking units is within a predetermined range, reliability is improved, and adhesion is also improved.

A substrate according to an aspect of the present invention comprises the thin film capacitor according to any of the above. An electronic device according to an aspect of the present invention comprises the thin film capacitor according to any of the above.

### BRIEF DESCRIPTION OF THE DRAWING(S)

FIG. 1 is a schematic sectional view of a main part of a thin film capacitor according to an embodiment of the present invention;

FIG. 2 is a schematic sectional view of a main part of a thin film capacitor according to another embodiment of the present invention; and

FIG. 3 is a schematic view showing a method of measuring adhesion strength (peel strength).

### DETAILED DESCRIPTION OF THE INVENTION

Hereinafter, embodiments of the present invention are described in detail.

### First Embodiment

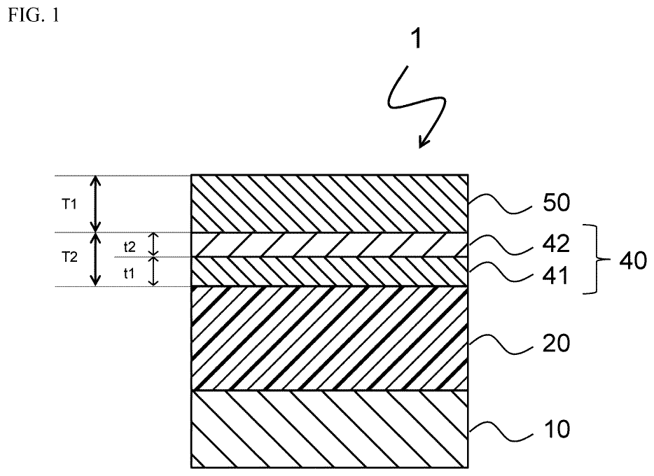

As shown in FIG. 1, a thin film capacitor 1 according to the present embodiment includes a first electrode layer 10, a second electrode layer 50, and a dielectric layer 20 provided between the first electrode layer 10 and the second electrode layer 50. In the present embodiment, an intermediate layer 40 is provided between the dielectric layer 20 and the second electrode layer 50. The shape of the thin film capacitor 1 is not limited, but is normally a rectangular parallelepiped shape. The dimensions of the thin film capacitor 1 are not limited either, and the thickness and length of the thin film capacitor 1 are determined depending on the application and the like.

### (First Electrode Layer)

The first electrode layer 10 may be formed, for example, on a substrate (not shown). Alternatively, the first electrode layer 10 may also serve as a substrate. The thickness of the first electrode layer 10 is not limited, but may be, for example, 0.01 to 100 μm. The first electrode layer 10 is an electrode that sandwiches the dielectric layer 20 together with the second electrode layer 50 and allows the thin film capacitor to function as a capacitor.

The first electrode layer 10 is made of a conductive material. Examples of the conductive material include: simple metals such as Au, Pt, Ag, Ir, Ru, Co, Ni, Fe, Cu, and Al; alloys of these metals; semiconductors such as Si, GaAs, GaP, InP, and SiC; and conductive metal oxides such as ITO, ZnO, and SnO₂. As the conductive material, it is preferable to use a material containing a base metal. As the material containing a base metal, it is particularly preferable to use a simple substance of Ni, a simple substance of Cu, or a Ni—Cu alloy.

### (Substrate)

When the first electrode layer 10 is formed on a substrate (not shown), the type of substrate is not limited. The substrate is made of a material that is chemically and thermally stable, does not easily generate stress on the substrate, and can maintain the smoothness of the surface of the substrate.

Examples of the substrate include: single crystal substrates composed of Si single crystal, sapphire single crystal, SrTiO₃ single crystal, MgO single crystal, etc.; ceramic polycrystalline substrates composed of alumina (Al₂O₃), magnesia (MgO), forsterite (2MgO·SiO₂), steatite (MgO ·SiO₂), mullite (3Al₂O_{3.2}SiO₂), beryllia (BeO), zirconia (ZrO₂), aluminum nitride (AlN), silicon nitride (Si₃N₄), silicon carbide (SiC), etc.; glass ceramic substrates (LTCC substrates) composed of alumina (crystalline phase), silicon oxide (glass phase), and the like and obtained by firing at 1000° C. or less; glass substrates such as quartz glass; and metal substrates composed of Fe—Ni alloys, etc. Also, the substrate may be a metal foil composed of nickel (Ni) or copper (Cu).

The thickness of the substrate is not limited and may be, for example, 10 μm to 5000 μm. The resistivity of the substrate varies depending on the material to be used. If the substrate is made of a material having a low resistivity, electric current leakage may occur during operation of the thin film capacitor. As a result, the electrical characteristics of the thin film capacitor may be affected. Thus, when the substrate has a low electrical resistivity, it is preferable to perform an insulation treatment on the surface of the substrate so as to make it difficult for the electric current generated during operation of the thin film capacitor to flow to the substrate.

For example, when the substrate is a Si single crystal substrate, it is preferable to form an insulating layer on the surface of the substrate. The material constituting the insulating layer is not limited and is a material that can ensure sufficient insulation. Examples of the insulating layer include SiO₂, Al₂O₃, and Si₃Nₓ. Also, the thickness of the insulating layer is not limited and may be 0.01 μm or more and 1 μm or less.

### (Dielectric Layer)

In the present embodiment, the dielectric layer 20 is directly formed on the surface of the first electrode layer 10. The main component of the dielectric composition constituting the dielectric layer 20 is not limited and is composed of, for example, an oxide dielectric (including an oxynitride dielectric) containing an oxide (including an oxynitride). Specifically, the following dielectric materials are exemplified. Examples of the main component of the dielectric layer 20 include a dielectric having a perovskite crystal structure, a bismuth layered compound, and a dielectric having a tungsten bronze crystal structure.

Examples of the dielectric having a perovskite structure include (Ba, Ca)(Ti, Zr)O₃ (barium titanate, etc.), (Ca, Sr)(Ti, Zr)O₃ (calcium titanate, strontium titanate, etc.), (K, Na)NbO₃, and (Bi, Na)TiO₃. Examples of the bismuth layered compound include Bi₄Ti₃O₁₂ and SrBi₂Ta₂O₉.

Examples of the dielectric having a tungsten bronze crystal structure include Ba(Nb, Ta)₂O₆, Ca (Nb, Ta)₂O₆, (Sr_{X}Ba_{1-X})Nb₂O₆, (K, Na)Sr₂Nb₅O₁₅, Ba₃TiNb₄O₁₅, Ba₂LaTi₂Nb₃O₁₅, (Ba, Sr)Ta₄O₁₂, Ba_{5.75}(Zr_{1.5}Ta_{8.5})O₃₀, and Ba_{4.0}La_{2.0}Zr_{4.0}(Nb_{0.5}Ta_{0.5})₆O₃₀. Examples of other dielectric materials include BMT(Ba(Mg_{1/3}Ta_{2/3})O₃).

In addition to the main component of the above-described dielectric composition, the dielectric layer 20 may further include a subcomponent. The type and amount of the subcomponent are determined depending on the desired characteristics. Examples of the subcomponent include: an oxide of at least one element selected from manganese (Mn), chromium (Cr), cobalt (Co), nickel (Ni), and iron (Fe); an oxide of at least one element selected from vanadium (V), molybdenum (Mo), and tungsten (W); an oxide of a rare earth element; an oxide of magnesium (Mg); and an oxide of at least one element selected from silicon (Si), lithium (Li), aluminum (Al), germanium (Ge), barium (Ba), calcium (Ca), and boron (B).

Note that, the dielectric layer 20 may include pores, trace impurities, and other subcomponents to the extent that characteristics, such as relative permittivity, specific resistance, withstand voltage, and highly accelerated lifetime test, are not deteriorated. For example, the dielectric layer 20 may include Zn, Cu, Ga, etc.

The thickness of the dielectric layer 20 is not limited, but is preferably set to, for example, 50 nm or more and 8000 nm or less or to 50 nm or more and 6000 nm or less. In such a range, sufficient capacitance can be ensured while reducing leakage electric current. Also, reliability is improved.

### (Intermediate Layer)

The intermediate layer 40 is formed on the dielectric layer 20. In the present embodiment, the intermediate layer 40 has one stacking unit consisting of a first intermediate layer 41 and a second intermediate layer 42, and the first intermediate layer 41 is in contact with the dielectric layer 20. The second intermediate layer 42 is in contact with the first intermediate layer 41, and the second electrode layer 50 is in contact with the surface of the second intermediate layer 42.

The first intermediate layer 41 includes a first metal M1 as a main component, and the second intermediate layer 42 includes a second metal M2, which is different from the first metal M1, as a main component. Note that, in the present specification, the main component means that the atomic ratio of the metal layer exceeds 50%.

The first metal (M1) is at least one selected from a group consisting of Cu, Cr, Mo, Ti, and W and is preferably Cu, Cr, and Ti. The second metal (M2) is at least one selected from a group consisting of Ni, Pd, Pt, Au, Ru, Rh, and Ir and is preferably Ni, Pd, Pt, and Au.

Note that, the main components of the first intermediate layer 41 and the second intermediate layer 42 may be single metals different from each other, and each purity may be 99 at % or more. Alternatively, the combination of main components in the first intermediate layer 41 and the second intermediate layer 42 may be a combination of mutually different alloys or a combination of an alloy and a metal.

The thickness t1 of the first intermediate layer 41 is not limited, but is preferably 8 nm or more and 80 nm or less and is more preferably 8 nm or more and 50 nm or less. The thickness t2 of the second intermediate layer 42 is not limited, but is preferably 8 nm or more and 80 nm or less and is more preferably 8 nm or more and 50 nm or less.

The thickness t1 of the first intermediate layer 41 and the thickness t2 of the second intermediate layer 42 can be measured by processing the thin film capacitor 1 including the intermediate layer 40 with a focused ion beam (FIB) processing device and observing the obtained cross section with a scanning electron microscope (SEM). Note that, if the first intermediate layer 41 and the second intermediate layer 42 cannot be distinguished by the SEM, the first intermediate layer 41 and the second intermediate layer 42 may be distinguished by crystal orientation observation with a transmission electron microscope (TEM), crystal orientation observation with an electron backscatter diffraction (EBSD), or the like. The thickness of each of the first electrode layer 20 and the second electrode layer 50 can also be measured by a similar method.

The thickness ratio (t2/t1) of the second intermediate layer 42 to the first intermediate layer 41 is not limited, but is preferably 0.2 to 1.0 and is more preferably 0.32 to 0.64. In such a range, the adhesion strength between the second electrode layer 50 and the dielectric layer 20 is improved, and reliability such as highly accelerated lifetime test is also improved.

### (Second Metal Layer)

In the present embodiment, the second electrode layer 50 is formed on the surface of the second intermediate layer 42 of the intermediate layer 40. As with the first electrode layer 10, the second electrode layer 50 is made of a conductive material. Examples of the conductive material constituting the second electrode layer 50 include the same material as the conductive material constituting the first electrode layer 10, but they do not need to be exactly the same and may be made of different materials. For example, when the first electrode layer 10 is made of Ni or a Ni alloy, the second electrode layer 50 may be made of Cu, a Cu alloy, or the like.

The thickness T1 of the second electrode layer 50 is not limited, but is preferably adjusted so as to be larger than the total thickness T2 of the intermediate layer 40. For example, T1 is approximately 5 to 70 times larger than T2. The thickness T1 of the second electrode layer 50 is not limited, but can be, for example, 0.01 to 100 μm and is preferably equal to or larger than the thickness of the first electrode layer 10, but may be smaller than the thickness of the first electrode layer 10.

### (Method of Manufacturing Thin Film Capacitor)

Next, an example of a method of manufacturing a thin film capacitor 1 shown in FIG. 1 is described below. First, a first electrode layer 10 is formed on a substrate (not shown). Alternatively, the first electrode layer 10 may be a metal foil that also serves as a substrate.

Then, a dielectric layer 20 is formed on the first electrode layer 10. The method of forming the dielectric layer 20 is not limited, and various film forming methods can be used. Examples of film forming methods include vacuum evaporation, sputtering, pulsed laser deposition (PLD), metal-organic chemical vapor deposition (MO-CVD), metal-organic decomposition (MOD), sol-gel method, and chemical solution deposition (CSD). These film forming methods can also be used as methods of forming the first electrode layer 10 on the substrate.

The raw materials used for forming the dielectric layer 20 (evaporation materials, various target materials, organic metal materials, etc.) may contain trace amounts of impurities, subcomponents, etc., but this is acceptable as long as the effects of the present invention are not disturbed.

Next, an intermediate layer 40 consisting of a first intermediate layer 41 and a second intermediate layer 42 is formed in a predetermined number of stacking units on the formed dielectric layer 20 by repeatedly using the film forming method as described above. In the embodiment shown in FIG. 1, the number of stacking units is one. Examples of an apparatus for alternately forming the first intermediate layers 41 and second intermediate layers 42, which are relatively thin, include a carousel type sputtering apparatus, but a multi-target type sputtering apparatus, such as a load lock type and a cluster type, may be used. The thicknesses of the first intermediate layer 41 and the second intermediate layer 42 can be controlled by, for example, controlling the sputtering time.

After that, a second metal layer 50 is formed on the intermediate layer 40. The method of forming the second metal layer 50 is not limited and may be a plating method in addition to any of the above-mentioned film forming methods.

An annealing treatment may be performed before or after forming the second metal layer 50. The annealing conditions are not limited. For example, the annealing treatment is preferably performed at an annealing temperature of 300° C. to 1000° C. and an annealing time of 30 minutes to 120 minutes in an atmosphere where the electrode layer 50 or 10 is not oxidized. The atmosphere where the electrode layer 50 or 10 is not oxidized means an atmosphere where the oxygen content is 1% or less.

Through the above steps, as shown in FIG. 1, a thin film capacitor 1 is obtained in which the dielectric layer 20, the intermediate layer 40, and the second electrode layer 50 are stacked in this order on the first electrode layer 10.

### Summary of Present Embodiment

In the thin film capacitor 1 according to the present embodiment, it is possible to set the thickness of the first intermediate layer 41 in contact with the dielectric layer 20 to, for example, less than 100 nm and to set the thickness of the second intermediate layer 42 to, for example, less than 100 nm, and in addition, the adhesion strength between the dielectric layer 20 and the second electrode layer 50 can be improved. Moreover, in the thin film capacitor 1, reliability such as highly accelerated lifetime test is improved compared to the conventional capacitors.

The reason for this is, for example, as follows. The first metal M1, which is the main component of the first intermediate layer 41, reacts with oxygen contained in the dielectric layer 20 during an annealing treatment of the second electrode layer 50 and is strongly bonded with the dielectric layer 20. During the heat treatment, the first metal, which is the main component of the first intermediate layer 41, and the second metal M2, which is the main component of the second intermediate layer 42, are alloyed, the first metal M1 is prevented from excessively reacting with the dielectric layer 20, the characteristics of the dielectric layer 20 are prevented from deteriorating, and reliability such as highly accelerated lifetime test is also improved. Moreover, since the first intermediate layer 41 and the second intermediate layer 42 are thin within a predetermined range, the first metal M1 is prevented from excessively reacting with the dielectric layer 20, and the characteristics of the dielectric are prevented from deteriorating.

Note that, preferably, the first metal M1 is a metal that reacts more with the dielectric layer 20 than the second metal M2 during heat treatment such as annealing of the second electrode layer 50. Preferably, the second metal M2 is a metal that forms an alloy with the first metal M1 during heat treatment such as annealing of the second electrode layer 50 and prevents the first metal M1 from moving toward the dielectric layer 20.

### Second Embodiment

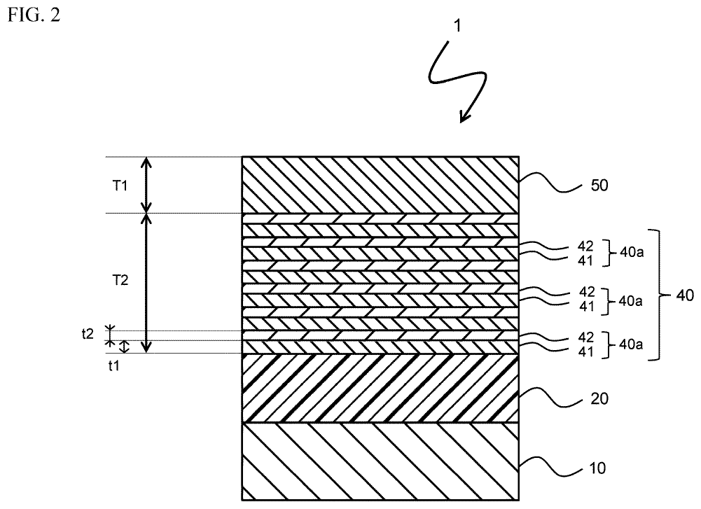

As shown in FIG. 2, except that an intermediate layer 40 has a stacking structure of two or more stacking units 40a, a thin film capacitor 1a according to the present embodiment is similar to the thin film capacitor 1 according to First Embodiment described above and has configurations and effects similar to those of the thin film capacitor 1 according to First Embodiment described above. Hereinafter, different matters from First Embodiment are mainly described, and overlapping matters are not partly described.

In the thin film capacitor 1a, a first intermediate layer 41 is formed in contact with the surface of a dielectric layer 20, and a second intermediate layer 42 is stacked and formed thereon to constitute one stacking unit 40a. A first intermediate layer 41, which is another stacking unit, is formed on the second intermediate layer 42 of the stacking unit 40a while being in contact therewith, and the second intermediate layer 42 is stacked and formed thereon to constitute another stacking unit 40a. In this way, the stacking units 40a are repeated in a predetermined number of times to form the intermediate layer 40.

The number of repetition of the stacking units 40a in the intermediate layer 40 is not limited, but is preferably smaller from the viewpoint of adhesion (peel strength). For example, the number of repetition of the stacking units 40a in the intermediate layer 40 is preferably 10 or less and is more preferably 8 or less. From the viewpoint of reliability (highly accelerated lifetime test), the number of repetition of the stacking units 40a is preferably 2 to 10 and is more preferably 4 to 10 or more preferably 4 to 8.

### Third Embodiment

A thin film capacitor of the present embodiment is a modification of the thin film capacitor 1a shown in FIG. 2. The thin film capacitor of the present embodiment is similar to the thin film capacitor 1a according to Second Embodiment described above and have configurations and effects similar to those of the thin film capacitor 1a according to Second Embodiment described above, except that: the first intermediate layer 41 includes a second metal (M2) as a main component; the second intermediate layer 42 includes a first metal (M1) as a main component; and a preferable thickness ratio of the intermediate layers 41 and 42 (t2/t1) is different. Hereinafter, different matters from Second Embodiment are mainly described, and overlapping matters are not partly described.

In this thin film capacitor 1a, unlike Second Embodiment, the first intermediate layer 41 includes the second metal (M2) as a main component, and the second intermediate layer 42 includes the first metal (M1), which is different from the second metal, as a main component. That is, the first intermediate layer 41 includes, for example, Ni as a main component, and the second intermediate layer 42 includes Cu as a main component.

In the present embodiment, the thickness ratio (t2/t1) of the second intermediate layer 42 to the first intermediate layer 41 is not limited, but is preferably 1 to 5 and is more preferably 1.5 to 3.2. In such a range, the adhesion strength between the second electrode layer 50 and the dielectric layer 20 is improved, and reliability such as highly accelerated lifetime test is also improved.

In the thin film capacitor 1a of this embodiment, the thickness of the first intermediate layer 41 in contact with the dielectric layer 20 is as thin as 80 nm or less, and the thickness of the second intermediate layer 42 is also as thin as 80 nm or less. Since the first intermediate layer 41 and the second intermediate layer 42, which are comparatively thin, are formed so that the first intermediate layer 41 is in contact with the dielectric layer 20, the adhesion strength between the dielectric layer 20 and the second electrode layer 50 is improved, and the reliability (highly accelerated lifetime test) is improved at the same time.

The reason for this is, for example, as follows. The first metal M1, which is the main component of the second intermediate layer 42, is diffused into the first intermediate layer 41, which is comparatively thin, and reacts with the dielectric layer 20 during an annealing treatment of the second electrode layer 50. Then, the first metal M1 reacts with oxygen contained in the dielectric layer 20 and is strongly bonded with the dielectric layer 20. During the heat treatment, the second metal M2, which is the main component of the first intermediate layer 41, and the first metal M1, which is the main component of the second intermediate layer 42, are alloyed, the first metal M1 is prevented from excessively reacting with the dielectric layer 20, the characteristics of the dielectric layer 20 are prevented from deteriorating, and reliability such as highly accelerated lifetime test is also improved. Moreover, since the first intermediate layer 41 and the second intermediate layer 42 are thin within a predetermined range, the first metal M1 is prevented from excessively reacting with the dielectric layer 20, and the characteristics of the dielectric are prevented from deteriorating.

From this point of view, preferably, the first metal M1 is a metal that has a faster diffusion rate than the second metal M2 and reacts with the dielectric layer 20 more than the second metal M2 during heat treatment such as annealing of the second electrode layer 50. Preferably, the second metal M2 is a metal that forms an alloy with the first metal M1 and prevents the first metal M1 from moving toward the dielectric layer 20 during heat treatment such as annealing of the second electrode layer 50.

Hereinabove, First to Third Embodiments are described, but the present invention is not limited to the above-described embodiments at all and may be modified in various modes within the scope of the present invention.

For example, the use of the thin film capacitor of each embodiment is not limited. For example, the thin film capacitors described above may be used as snubber capacitors used in DC-DC converters, inverter circuits, or the like. Also, the thin film capacitors may be mounted on a power supply module or the like. Also, the thin film capacitors may be used by being embedded in, for example, a circuit board. Also, the thin film capacitors may be used by being incorporated into electronic devices including a power supply module, such as digital television, server, and in-vehicle equipment.

### EXAMPLES

Hereinafter, the present invention is described based on more detailed examples, but the present invention is not limited to these examples.

Hereinafter, examples and comparative examples of the present invention are described in detail, but the present invention is not limited to the following examples.

### Example 1

As a first electrode layer 10, a Ni foil having a thickness of 28 μm was prepared. A dielectric layer 20 made of barium titanate was formed on the first electrode layer 10 by sputtering so as to have a thickness of 600 nm. A first intermediate layer 41 made of Cu with a film thickness t1=25 nm and a second intermediate layer 42 made of Ni with a thickness t2=16 nm were stacked in this order and formed by sputtering on the dielectric layer 20, and an intermediate layer 40 consisting of one stacking unit was formed. Then, a second electrode layer 50 made of Cu and formed by sputtering so as to have a film thickness T1=2500 nm was formed on the intermediate layer 40, and a thin film capacitor 1 was obtained.

### Peel Strength (Adhesion)

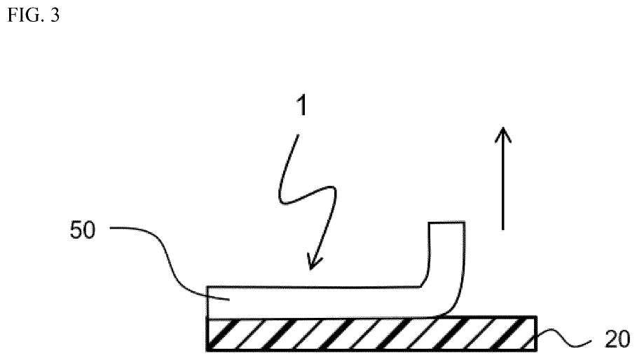

A sample of a thin film capacitor with cuts made at a pitch of 1 cm was prepared and adhered onto a glass substrate with tape. After that, as shown in FIG. 3, an end of the second electrode layer 50 was partially peeled off from the dielectric layer 20, and a peel strength was measured using a peel tester (manufactured by Aiko Engineering) based on, for example, JIS K 6854-1:1999. The grip movement speed was 100 mm/min. The results are shown in Table 1. Note that, in FIG. 3, the intermediate layer 40 shown in FIG. 1 is not illustrated, but most part of the intermediate layer 40 is actually in close contact with the second electrode layer 50 and peeled off from the surface of the dielectric layer 20 together with the second electrode layer 50.

### Highly Accelerated Lifetime Test (Reliability HALT)

A sample of a thin film capacitor was placed in a thermostatic oven and heated to a temperature of 135° C. Once that temperature was reached, a voltage of 4V was applied to the capacitor sample to start a test. The temperature of 135° C. was maintained for 133 hours, the resistance was continuously measured during that time, and the time when the resistance dropped by one order was determined to be a highly accelerated lifetime test. If the insulation resistance did not drop by one order or more even after maintaining the temperature of 135° C. for 133 hours, the highly accelerated lifetime test was considered to be 133 hours. The results are shown in Table 1.

### Example 2

Except for changing the thickness of the first intermediate layer 41 to 50 nm, a thin film capacitor was manufactured in the same manner as in Example 1 and evaluated in the same manner as in Example 1. The results are shown in Table 1.

### Examples 3 to 7

Thin film capacitors were formed in the same manner as in Example 1 and evaluated in the same manner as in Example 1, except that stacking units 40a were formed by being repeatedly stacked so that the number of repetition (number of layers in the table) of the stacking units 40a of an intermediate layer 40 was set to the number (number of layers) listed in Table 1 by alternately repeating sputtering with different target materials. The results are shown in Table 1. In Table 1, for example, the number of layers of 2 means that the stacking units 40a shown in FIG. 2 were repeated twice to be formed, and then a second electrode layer 50 was formed thereon. Also, the number of layers of 10 means that the stacking units 40a shown in FIG. 2 were repeated 10 times to be formed, and then a second electrode layer 50 was formed thereon.

### Examples 8 to 10

Thin film capacitors were formed in the same manner as in Example 4 and evaluated in the same manner as in Example 1, except that the thickness of a first intermediate layer and the thickness of a second intermediate layer were adjusted to the values listed in Table 1. The results are shown in Table 1.

### Comparative Example 1

A thin film capacitor was formed in the same manner as in Example 1 and evaluated in the same manner as in Example 1, except that a first intermediate layer 41 made of Ni with a thickness of 500 nm was directly formed on a dielectric layer by sputtering without forming a second intermediate layer made of Cu. The results are shown in Table 1.

### Comparative Example 2

A thin film capacitor was formed in the same manner as in Example 1 and evaluated in the same manner as in Example 1, except that a second electrode layer was formed by directly performing Cu sputtering on a dielectric layer after forming the dielectric layer. The results are shown in Table 1.

### (Evaluation)

As shown in Table 1, it was found that each of Examples with the predetermined structure can achieve both peel strength and highly accelerated lifetime test (reliability HALT) at a higher level than in Comparative Examples 1 and 2. In particular, as shown in Examples 3 to 7, it was found that when the number of repetition (number of layers) of stacking units of the intermediate layer is 2 to 10, the adhesion strength and the reliability tend to be favorable.

It was also found that, as shown in Examples 4 and 8 to 10, when the ratio t2/t1 of the thickness t2 of the second intermediate layer to the thickness t1 of the first intermediate layer is adjusted to a predetermined range, reliability can be further improved with sufficiently high peel strength than in Comparative Example 1.

### Example 11

A thin film capacitor was formed in the same manner as in Example 5, except that the dielectric layer 20 was made of tungsten bronze (Ba_{4.0}La_{2.0}Zr_{4.0}(Nb_{0.5}Ta_{0.5})₆O₃₀) with a film thickness of 5000 nm. The peel strength was measured in the same manner as in Example 1. Moreover, the highly accelerated lifetime test was determined under the following conditions.

### Highly Accelerated Lifetime Test (Reliability HALT)

A sample of a thin film capacitor was placed in a thermostatic oven and heated to a temperature of 125° C. Once that temperature was reached, a voltage of 400V was applied to the capacitor sample to start a test. The temperature of 125° C. was maintained for 100 hours, the resistance was continuously measured during that time, and the time when the resistance dropped by one order was determined to be a highly accelerated lifetime test. If the insulation resistance did not drop by one order or more even after maintaining the temperature of 125° C. for 100 hours, the highly accelerated lifetime test was considered to be 100 hours. The results are shown in Table 2.

### Comparative Example 3

A thin film capacitor was formed in the same manner as in Example 11 and evaluated in the same manner as in Example 11, except that a first intermediate layer 41 made of Ni with a thickness of 500 nm was directly formed on a dielectric layer by sputtering without forming a second intermediate layer made of Cu. The results are shown in Table 2.

### (Evaluation)

As shown in Table 2, it was found that even in Example 11, in which the dielectric layer is made of tungsten bronze material, both peel strength and highly accelerated lifetime test (reliability HALT) can be achieved at a higher level than in Comparative Example 3. In particular, it was found that the peel strength is improved by 7 times or more compared to that in Comparative Example 3.

### Examples 12 to 16

Thin film capacitors were formed in the same manner as in Examples 4 to 8, respectively, and evaluated in the same manner as in Example 1, except that: the metal type of the first intermediate layer was changed to Ni; the metal type of the second intermediate layer was changed to Cu; and each thickness was changed to the value listed in Table 3. The results are shown in Table 3.

As shown in Table 3, it was found that both peel strength and highly accelerated lifetime test (reliability HALT) can be achieved in each Example as compared with Comparative Example 1 and Comparative Example 2. It was also found that, in Examples 12 to 16, in which the metals of M1 and M2 are replaced compared to Examples 4 to 8, t2/t1 is preferably 1 or more. It was also found that both peel strength and highly accelerated lifetime test (reliability HALT) were improved in Examples 4 to 8 compared to those in Examples 12 to 16.

### Example 17

A thin film capacitor was formed in the same manner as in Example 11 and evaluated in the same manner as in Example 11, except that: the metal type of the first intermediate layer was changed to Ni, the metal type of the second intermediate layer was changed to Cu; and the thicknesses of the first intermediate layer and the second intermediate layer were changed to the values listed in Table 4. The results are shown in Table 4.

As shown in Table 4, it was found that both peel strength and highly accelerated lifetime test (reliability HALT) can be achieved at a higher level even in Example 17, in which the dielectric layer is made of tungsten bronze, compared to in Comparative Example 3. Note that, it was found that, compared to in Example 17, both peel strength and highly accelerated lifetime test (reliability HALT) are improved in Example 11.

TABLE 1

| | | Adhesion Layer | | | | | | | | | |
|---|---|---|---|---|---|---|---|---|---|---|---|
| | | | | | | | | | | | 4 V |
| | | First Intermediate Layer | | Second Intermediate Layer | | | | | Second | | Highly |
| | Dielectric | | Thickness | | Thickness | | Number | | Metal Layer | Peel | Accelerated |
| | Layer | | dl | | d2 | | of | T2 | T1 | Strength | Lifetime Test |
| | Material | Type of Metal | (nm) | Type of Metal | (nm) | d2/d1 | Layers | (nm) | (nm) | (N/cm) | (h) |
| Ex. 1 | BaTiO3 | Cu | 25 | Ni | 16 | 0.64 | 1 | 41 | 2500 | 3.86 | 70.5 |
| Ex. 2 | BaTiO3 | Cu | 50 | Ni | 16 | 0.32 | 1 | 66 | 2500 | 4.03 | 67.5 |
| Ex. 3 | BaTiO3 | Cu | 25 | Ni | 16 | 0.64 | 2 | 82 | 2500 | 3.61 | 99.5 |
| Ex. 4 | BaTiO3 | Cu | 25 | Ni | 16 | 0.64 | 4 | 164 | 2500 | 3.33 | 123.0 |
| Ex. 5 | BaTiO3 | Cu | 25 | Ni | 16 | 0.64 | 6 | 246 | 2500 | 3.31 | 133.0 |
| Ex. 6 | BaTiO3 | Cu | 25 | Ni | 16 | 0.64 | 8 | 328 | 2500 | 3.11 | 128.0 |
| Ex. 7 | BaTiO3 | Cu | 25 | Ni | 16 | 0.64 | 10 | 410 | 2500 | 3.04 | 126.8 |
| Ex. 8 | BaTiO3 | Cu | 8 | Ni | 8 | 1 | 4 | 64 | 2500 | 3.43 | 76.0 |
| Ex. 4 | BaTiO3 | Cu | 25 | Ni | 16 | 0.6 | 4 | 164 | 2500 | 3.33 | 123.0 |
| Ex. 9 | BaTiO3 | Cu | 50 | Ni | 16 | 0.32 | 4 | 264 | 2500 | 3.75 | 95.8 |
| Ex. 10 | BaTiO3 | Cu | 50 | Ni | 10 | 0.2 | 4 | 240 | 2500 | 3.87 | 77.0 |
| Comp. Ex. 1 | BaTiO3 | Ni | 500 | N/A | 0 | — | 0 | 500 | 2500 | 1.01 | 61.1 |
| Comp. Ex. 2 | BaTiO3 | N/A | 0 | N/A | 0 | — | 0 | 0 | 2500 | 4.18 | 22.8 |

TABLE 2

| | | Adhesion Layer | | | | | | | | | |
|---|---|---|---|---|---|---|---|---|---|---|---|
| | | | | | | | | | | | 400 V |
| | | First Intermediate Layer | | Second Intermediate Layer | | | | | Second | | Highly |
| | Dielectric | | Thickness | | Thickness | | Number | | Metal Layer | Peel | Accelerated |
| | Layer | Type of | d1 | Type of | d2 | | of | T2 | T1 | Strength | Lifetime Test |
| | Material | Metal | (nm) | Metal | (nm) | d2/d1 | Layers | (nm) | (nm) | (N/cm) | (h) |
| Ex. 11 | TB | Cu | 25 | Ni | 16 | 0.64 | 6 | 246 | 2500 | 3.38 | 119.7 |
| Comp. Ex. 3 | TB | Ni | 500 | N/A | 0 | — | 0 | 500 | 2500 | 0.44 | 98.6 |

TABLE 3

| | | Adhesion Layer | | | | | | | | | 4 V |
|---|---|---|---|---|---|---|---|---|---|---|---|
| | | | | | | | | | | | Highly |
| | | First Intermediate Layer | | Second Intermediate Layer | | | | | Second | | Accelerated |
| | Dielectric | | Thickness | | Thickness | | Number | | Metal Layer | Peel | Lifetime |
| | Layer | | d1 | | d2 | | of | T2 | T1 | Strength | Test |
| | Material | Type of Metal | (nm) | Type of Metal | (nm) | d2/d1 | Layers | (nm) | (nm) | (N/cm) | (h) |
| Ex. 12 | BaTiO3 | Ni | 16 | Cu | 25 | 1.56 | 4 | 164 | 2500 | 2.59 | 114.2 |
| Ex. 13 | BaTiO3 | Ni | 16 | Cu | 25 | 1.56 | 6 | 246 | 2500 | 2.49 | 118.2 |
| Ex. 14 | BaTiO3 | Ni | 16 | Cu | 25 | 1.56 | 8 | 328 | 2500 | 2.42 | 117.4 |
| Ex. 15 | BaTiO3 | Ni | 16 | Cu | 25 | 1.56 | 10 | 410 | 2500 | 2.35 | 115.1 |
| Ex. 16 | BaTiO3 | Ni | 8 | Cu | 8 | 1 | 4 | 64 | 2500 | 2.37 | 72.1 |
| Comp. Ex. 1 | BaTiO3 | Ni | 500 | N/A | 0 | — | 0 | 500 | 2500 | 1.01 | 61.1 |
| Comp. Ex. 2 | BaTiO3 | N/A | 0 | N/A | 0 | — | 0 | 0 | 2500 | 4.18 | 22.8 |

TABLE 4

| | | Adhesion Layer | | | | | | | | | 400 V |
|---|---|---|---|---|---|---|---|---|---|---|---|
| | | | | | | | | | | | Highly |
| | | First Intermediate Layer | | Second Intermediate Layer | | | | | Second | | Accelerated |
| | Dielectric | | Thickness | | Thickness | | Number | | Metal Layer | Peel | Lifetime |
| | Layer | | d1 | | d2 | | of | T2 | T1 | Strength | Test |
| | Material | Type of Metal | (nm) | Type of Metal | (nm) | d2/d1 | Layers | (nm) | (nm) | (N/cm) | (h) |
| Ex. 17 | TB | Ni | 16 | Cu | 25 | 1.56 | 6 | 246 | 2500 | 2.54 | 113.1 |
| Comp. Ex. 3 | TB | Ni | 500 | N/A | 0 | — | 0 | 500 | 2500 | 0.44 | 98.6 |

### DESCRIPTION OF THE REFERENCE NUMERICAL

1, 1a . . . thin film capacitor
10 . . . first electrode layer
20 . . . dielectric layer
40 . . . intermediate layer
40a . . . stacking unit
41 . . . first intermediate layer
42 . . . second intermediate layer
50 . . . second electrode layer

What is claimed is:

1. A thin film capacitor comprising:
a first electrode layer;
a second electrode layer; and
a dielectric layer provided between the first electrode layer and the second electrode layer,
wherein
the thin film capacitor comprises an intermediate layer between the dielectric layer and the second electrode layer,
the intermediate layer comprises at least one stacking unit including a first intermediate layer and a second intermediate layer stacked in contact with the first intermediate layer,
the first intermediate layer of the at least one stacking unit closest to the dielectric layer is stacked in contact with the dielectric layer,
the first intermediate layer comprises a first metal (M1) as a main component, and
the second intermediate layer comprises a second metal (M2), different from the first metal, as a main component.

2. The thin film capacitor according to claim 1, wherein
the first intermediate layer has a thickness of 8 to 80 nm, and
the second intermediate layer has a thickness of 8 to 80 nm.

3. The thin film capacitor according to claim 1, wherein
the first metal (M1) comprises at least one selected from a group consisting of Cu, Cr, Au, Ru, Rh, Ir, Mo, Ti, and W, and
the second metal (M2) comprises at least one selected from a group consisting of Ni, Pd, Pt, Au, Ru, Rh, and Ir.

4. The thin film capacitor according to claim 1, wherein the at least one stacking unit comprises stacking units repeatedly stacked in a range of 2 to 10 in the intermediate layer.

5. The thin film capacitor according to claim 1, wherein a ratio (t2/t1) of a thickness (t2) of the second intermediate layer to a thickness (t1) of the first intermediate layer is 0.2 to 1.0.

6. A thin film capacitor comprising:
a first electrode layer;
a second electrode layer; and
a dielectric layer provided between the first electrode layer and the second electrode layer,
wherein
the thin film capacitor comprises an intermediate layer between the dielectric layer and the second electrode layer,
the intermediate layer comprises at least one stacking unit including a first intermediate layer and a second intermediate layer stacked in contact with the first intermediate layer,
the first intermediate layer of the at least one stacking unit closest to the dielectric layer is stacked in contact with the dielectric layer,
the first intermediate layer comprises a second metal (M2) as a main component,
the second intermediate layer comprises a first metal (M1), different from the second metal, as a main component,
the first intermediate layer has a thickness of 8 to 80 nm, and
the second intermediate layer has a thickness of 8 to 80 nm.

7. The thin film capacitor according to claim 6, wherein the at least one stacking unit comprises stacking units repeatedly stacked in a range of 4 to 10 in the intermediate layer.

8. A substrate comprising the thin film capacitor according to claim 1.

9. An electronic device comprising the thin film capacitor according to claim 1.
